(19) United States
(12) Patent Application Publication
(10) Pub. No.: US 2015/0022972 A1
(43) Pub. Date: Jan. 22, 2015

(54) COOLING DEVICE

(71) Applicant: LSIS CO., LTD., Anyang-si (KR)

(72) Inventor: Hyuk Il KWON, Suwon-si (KR)

(73) Assignee: LSIS CO., LTD., Anyang-si (KR)

(21) Appl. No.: 14/320,394

(22) Filed: Jun. 30, 2014

(30) Foreign Application Priority Data
Jul. 22, 2013 (KR) 10-2013-0086119

(51) Int. Cl. H05K 1/02; F24F 7/007

(52) U.S. Cl. CPC H05K 1/0201; F24F 7/007
USPC 361/690; 454/254; 165/120

(57) ABSTRACT

The present disclosure provides a cooling device, the cooling device including a case including a first region and a second region isolated from the first region, a first cooling unit arranged at the first region to cool a first heat generating unit using an outside air, and a second cooling unit arranged at the second region to cool a second heat generating unit using inside air.

### CROSS-REFERENCE TO RELATED APPLICATIONS

Pursuant to 35 U.S.C.§119 (a), this application claims the benefit of earlier filing date and right of priority to Korean Patent Application No.10-2013-0086119, filed on Jul. 22, 2013, the contents of which are all hereby incorporated by reference herein in its entirety.

### BACKGROUND OF THE INVENTION

1. Field of the invention

The teachings in accordance with the exemplary embodiments of this present disclosure generally relate to a cooling device.

2. Description of Related Art

Generally, industrial electronic products or home electronic appliances are mounted with heat generating elements that generate a large amount of heat. For example, an inverter configured to convert a DC (Direct Current) to an AC (Alternating Current) generates a large amount of heat from a power semiconductor and peripherals thereof

The inverter is mounted with a heat sink for cooling a power semiconductor, where a forced cooling method using a cooling fan is used for the heat sink while a natural cooling method is used for peripherals that generate heat. However, the peripherals may be over-heated to decrease performance of the product or damage the product, when the natural cooling method is used to cool the peripherals.

### SUMMARY OF THE DISCLOSURE

An exemplary embodiment of the present disclosure is to provide a cooling device configured in such a manner that a heat generating unit arranged in an open space and coupled to a heat radiating member like a heat sink is forcibly cooled using an outside air, and a heat generating unit arranged in a closed space and not coupled to a heat sink is forcibly cooled using circulation of inside air, whereby a cooling efficiency of the heat generating unit can be enhanced.

Technical subjects to be solved by the present disclosure are not restricted to the above-mentioned problems, and any other technical problems not mentioned so far will be clearly appreciated from the following description by a person skilled in the art.

In one general aspect of the present disclosure, there is provided a cooling device, the cooling device comprising:

a case including a first region and a second region isolated from the first region;

a first cooling unit arranged at the first region to cool a first heat generating unit using an outside air; and

a second cooling unit arranged at the second region to cool a second heat generating unit using inside air.

Preferably, but not necessarily, the case may include a separator configured to separate the first region from the second region.

Preferably, but not necessarily, the cooling device may further comprise a circuit substrate arranged at an upper surface of the separator to be coupled to the first heat generating unit.

Preferably, but not necessarily, the first cooling unit may include a heat sink coupled to the first heat generating unit and a cooling fan configured to introduce the outside air to the first region, and the second cooling unit includes a support plate configured to support the second heat generating unit, and a circulation fan configured to circulate the inside air into the second region.

Preferably, but not necessarily, at least one distal end of one side of the support plate may be distanced from a lateral surface plate of the case, and the support plate may be formed with an opening coupled by the circulation fan.

Preferably, but not necessarily, the circulation fan may be arranged in parallel with the support plate.

Preferably, but not necessarily, the circulation fan may be slantly arranged relative to the support plate.

### ADVANTAGEOUS EFFECTS OF THE DISCLOSURE

The cooling device according to an exemplary embodiment of the present disclosure has an advantageous effect in that a heat generating unit arranged in an open space and coupled to a heat radiating member like a heat sink is forcibly cooled using an outside air, and a heat generating unit arranged in a closed space and not coupled to a heat sink is forcibly cooled using circulation of inside air.

### BRIEF DESCRIPTION OF DRAWINGS

FIG. 1 is a cross-sectional view illustrating a cooling device according to an exemplary embodiment of the present disclosure.

FIG. 2 is a plan view illustrating a circulation fan and a support plate of FIG. 1.

FIG. 3 is a cross-sectional view illustrating a cooling device according to another exemplary embodiment of the present disclosure.

### DETAILED DESCRIPTION OF THE DISCLOSURE

A cooling device according to exemplary embodiments of the present disclosure will be described more fully hereinafter with reference to the accompanying drawings.

Detailed descriptions of well-known functions, configurations or constructions are omitted for brevity and clarity so as not to obscure the description of the present disclosure with unnecessary detail. In the drawings, the width, length, thickness, etc. of components may be exaggerated or reduced for the sake of convenience. The present inventive concept may, however, be embodied in many different forms and should not be construed as limited to the example embodiments set forth herein. Rather, the described aspect is intended to embrace all such alterations, modifications, and variations that fall within the scope and novel idea of the present disclosure.

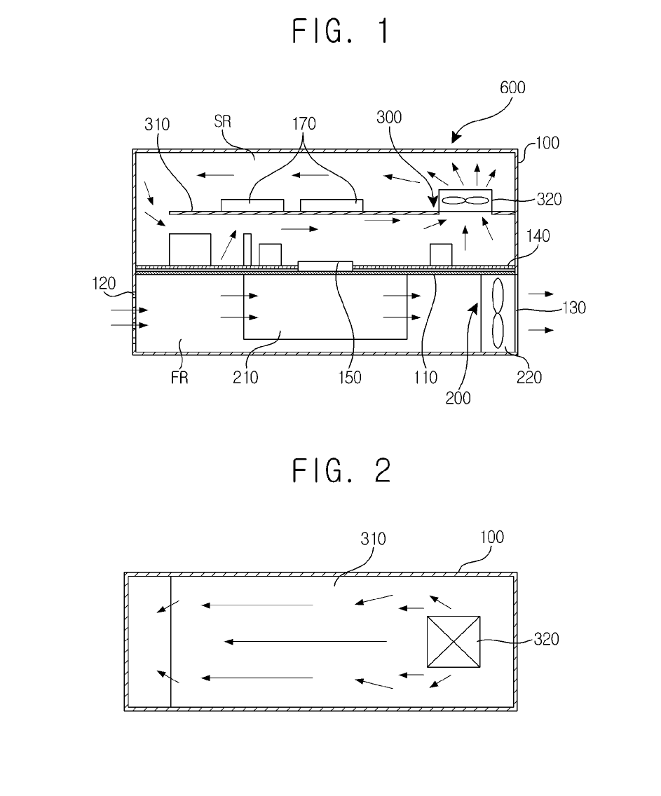

FIG. 1 is a cross-sectional view illustrating a cooling device according to an exemplary embodiment of the present disclosure, and FIG. 2 is a plan view illustrating a circulation fan and a support plate of FIG. 1.

Referring to FIGS. 1 and 2, the cooling device (600) includes a case (100), a first cooling unit (200) and a second cooling unit (300). The cooling device (600) according to an exemplary embodiment of the present disclosure may be widely installed on an industrial electronic products or home electronic appliances. Now, the explanation of the cooling device (600) according to an exemplary embodiment of the present disclosure is provided on an assumption that the cooling device (600) is installed on an inverter, as an industrial electronic product, that changes a DC to an AC having a frequency and a voltage that require a commercial AC power.

The case (100) provides a space for accommodating devices for implementing an inerter operation and the first/second cooling units (200, 300). The case (100) in the exemplary embodiment of the present disclosure may be divided into two spaces, for example. Hereinafter, the two spaces are defined as a first region (FR) and a second region (SR) separated from the first region (FR), where the first region (FR) may be an open space and the second region (SR) may be a closed space, for example.

In order to form two spaces inside the case (100), the case (100) may be formed with a separator configured to separate the first region from the second region. The separator (110) is arranged at a center of the case (100), and the case (100) is divided into two sections, that is the first region (FR) and the second region (SR).

The second region (SR) is arranged at an upper surface of the first region (FR) by the separator (110), and a part of the separator (110) is formed with an opening, where the opening formed by the separator (110) allows a first heat generating unit arranged at the second region (SR) to be coupled to a heat sink arranged at the first region (FR).

In the exemplary embodiment of the present disclosure, openings (120, 130) configured to introduce an outside air to and discharge the outside air from the first region (FR) are formed at an area corresponding to the first region (FR) of the case (100), where the second region (SR) is air-tightly closed to prevent entrance of foreign objects such as dust and the like.

Meantime, an upper surface of the separator (110) dividing an interior of the case (100) into the first and second regions (FR, SR) is arranged with a circuit substrate (140).

The circuit substrate (140) is formed at an upper surface with a first heat generating unit (150), where the circuit substrate (140) and the first heat generating unit (15) are electrically connected.

In the exemplary embodiment of the present disclosure, the first heat generating unit (150) may include a power semiconductor, and the first heat generating unit (150) may include an IGBT (Insulated Gate Bipolar Transistor), for example. Alternatively, the first heat generating unit (150) may include MOSFET (Metal Oxide Semiconductor Field Effect Transistor).

The first cooling unit (200) serves to cool the first heat generating unit (150). In the exemplary embodiment of the present disclosure, the first cooling unit (200) may be arranged at the first region (FR). The first cooling unit (200) arranged at the first region (FR) may include a heat sink (210) and a cooling fan (220).

The heat sink (210) may include aluminum or aluminum alloy having a higher heat conductivity than iron, and the heat sink (210) is coupled to the first heat generating unit (150) electrically connected to the circuit substrate (140) and radiates heat generated from the first heat generating unit (150) to the first region (FR).

The cooling fan (220) is arranged at the first region (FR), and the cooling fan (220) is arranged near to the opening (130) formed at the first region (FR). The cooling fan (220) serves to discharge an outside air to outside of the first region (FR). At this time, the outside air is introduced into the first region (FR) and heated via the heat sink (210).

The outside air introduced into the first region (FR) by the cooling fan (220) serves to cool the heat sink (210), whereby the first heat generating unit (150) coupled to the heat sink (210) is forcibly cooled by the cooling fan (220).

The second cooling unit (300) may be arranged at the second region (SR) in order to cool the second heat generating unit (170) arranged at the second region (SR). In the exemplary embodiment of the present disclosure, the second heat generating unit (170) may include a circuit substrate and at least one control module including control semiconductor chips, for example.

The second cooling unit (300) cools the second heat generating unit (170) by circulating an inside air circulating in the second heat generating unit (170) arranged at the closed second region (SR). The second cooling unit (300) may include a support plate (310) and a circulation fan (320) in order to cool the heat generating unit (170) in a circulation cooling method.

The support plate (310) is arranged at the second region (SR), and the support plate (310) is secured at a position distanced from the separator (110), an opening is formed at one side of the support plate (310) and the circulation fan (320, described later) is arranged at a position corresponding to the opening. The support plate (310) may be arranged in parallel with the separator (110), a distal end of the support plate (310) may be distanced from the case, and the separator (110) may be formed with the second heat generating unit (170).

The circulation fan (320) may be coupled to the support plate (31), the circulation fan (320) may be arranged at a position corresponding to the opening of the support plate (310), and the circulation fan (320) may be arranged in parallel with the support plate (310) and the separator (110).

The inside air of the second region (SR) is circulated by operation of the circulation fan (320), because a distal end of the support plat (310) is distanced from the case (100) and the opening formed at the support plate (310) is coupled to the circulation fan (320).

In the exemplary embodiment of the present disclosure, the first region (FR) arranged with the heat sink (210) is performed with a forcible cooling of the first heat generating unit (150) using an outside air by the cooling fan (220), and the closed second region (SR) is performed with the circulatory cooling of the second heat generating unit (170) by the inside air circulated by the circulation fan (320), whereby cooling efficiency of the first and second heat generating units (150, 170) can be further enhanced.

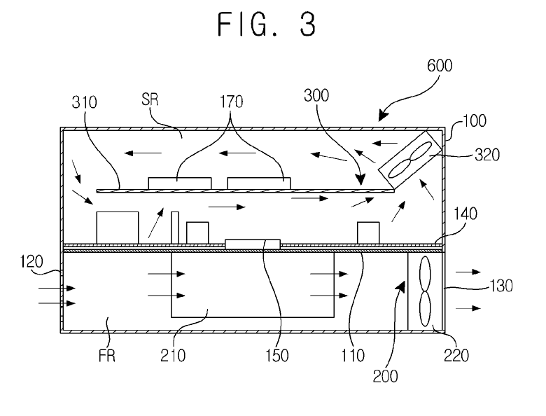

FIG. 3 is a cross-sectional view illustrating a cooling device according to another exemplary embodiment of the present disclosure.

The configuration of the cooling device according to another exemplary embodiment of the present disclosure is substantially same as that of FIGS. 1 and 2 except for arrangement of circulation fan. Thus, no redundant explanation on the same structure will be omitted, and, like reference numerals in FIG. 3 denote like elements.

Referring to FIG. 3, the circulation fan (320) may be slantly arranged or may be arranged to a slant direction relative to the support plate (310) in order to better circulate the inside air of the second region (SR), whereby the inside air of the second region (SR) can be more actively circulated by the circulation fan (320).

As apparent from the foregoing, a heat generating unit arranged at an opened space and coupled to heat radiating members like a heat sink is forcibly cooled using an outside air, and a heat generating unit arranged at a closed space and not coupled to the heat sink is forcibly cooled by circulation of inside air, whereby the cooling efficiency of heat units can be further enhanced by forced cooling.

Although the present disclosure has been described in detail with reference to the foregoing embodiments and advantages, many alternatives, modifications, and variations will be apparent to those skilled in the art within the metes and bounds of the claims. Therefore, it should be understood that the above-described embodiments are not limited by any of the details of the foregoing description, unless otherwise specified, but rather should be construed broadly within the scope as defined in the appended claims.

What is claimed is:

1. A cooling device, the cooling device comprising:
a case including a first region and a second region isolated from the first region;
a first cooling unit arranged at the first region to cool a first heat generating unit using an outside air; and
a second cooling unit arranged at the second region to cool a second heat generating unit using inside air.

2. The cooling device of claim 1, wherein the case includes a separator configured to separate the first region from the second region.

3. The cooling device of claim 2, further comprising a circuit substrate arranged at an upper surface of the separator to be coupled to the first heat generating unit.

4. The cooling device of claim 1, wherein the first cooling unit includes a heat sink coupled to the first heat generating unit and a cooling fan configured to introduce the outside air to the first region, and the second cooling unit includes a support plate configured to support the second heat generating unit, and a circulation fan configured to circulate the inside air into the second region.

5. The cooling device of claim 4, wherein at least one distal end of one side of the support plate is distanced from a lateral surface plate of the case, and the support plate is formed with an opening coupled by the circulation fan.

6. The cooling device of claim 4, wherein the circulation fan is arranged in parallel with the support plate.

7. The cooling device of claim 4, wherein the circulation fan is slantly arranged relative to the support plate.
